(19) United States
(12) Patent Application Publication
(10) Pub. No.: US 2025/0347641 A1
(43) Pub. Date: Nov. 13, 2025

(54) TECHNIQUES FOR REDUCING ELECTROMAGNETIC INTERFERENCE EFFECTS IN CHARGED PARTICLE MICROSCOPY

(71) Applicant: FEI Company, Hillsboro, OR (US)

(72) Inventors: James Vickers, San Jose, CA (US); Prasad Sabbineni, San Ramon, CA (US); Seema Somani, San Jose, CA (US); Blake Freeman, San Jose, CA (US); Scott Connors, Hillsboro, OR (US); Neel Leslie, San Jose, CA (US)

(21) Appl. No.: 19/275,535

(22) Filed: Jul. 21, 2025

Related U.S. Application Data
(63) Continuation of application No. PCT/US2024/012966, filed on Jan. 25, 2024.
(60) Provisional application No. 63/481,739, filed on Jan. 26, 2023.

(51) Int. Cl. G01N 23/2251; G06T 7/00; G06T 7/246

(52) U.S. Cl. CPC G01N 23/2251; G06T 7/001; G06T 7/248; G01N 2223/401; G01N 2223/611; G06T 2207/10016; G06T 2207/10061; G06T 2207/30148

(57) ABSTRACT

Embodiments of the present disclosure improve the performance of charged particle beam systems during imaging and/or microanalysis, at least in part by permitting a system and/or user to account for the influence of electromagnetic interference on beam direction and/or shape. Techniques are described for identifying, tracking, and/or correcting electromagnetic interference-induced beam drifts, as well as techniques for localizing defects in integrated circuit devices.

### CROSS-REFERENCE TO RELATED APPLICATIONS

This application is a continuation of International Application No. PCT/US2024/12966, filed on Jan. 25, 2024 and claims priority to and the benefit of U.S. Provisional Application No. 63/481,739, entitled “TECHNIQUES FOR REDUCING ELECTROMAGNETIC INTERFERENCE EFFECTS IN CHARGED PARTICLE MICROSCOPY”, filed on Jan. 26, 2023, the contents of which are incorporated herein in their entirety.

### TECHNICAL FIELD

Embodiments of the present disclosure are directed to charged particle microscope systems, as well as algorithms and methods for their operation. In particular, some embodiments are directed toward electronic fault analysis of nanostructured integrated circuits.

### BACKGROUND

Integrated circuit (IC) testing involves measurement of individual transistors or groups of transistors of a semiconductor wafer or wafer section (e.g., a diced wafer), termed a “device under test” or DUT, and such transistors have reached a characteristic size below the resolution limit of photon-optical systems, implicating the use of charged particle beam systems to resolve device features. A typical IC testing regime includes applying a periodic signal to a circuit at increasingly higher power, as an approach to examining circuit performance under different operating conditions and to determine at what point the circuit fails to operate to specifications.

During the course of generating charged particle beam imaging data of an active integrated circuit, electrical activity on the integrated circuit (IC) can generate electric and magnetic fields that perturb the electron beam within the imaging system. In a typical situation, an integrated circuit is coupled with a chip tester, and the chip tester exercises the integrated circuit in a periodic test loop. Activity on the integrated circuit draws device current that typically varies over the test loop, and that device current creates magnetic fields that can unintentionally steer the electron beam away from its desired target. These unintended beam shifts, which can be periodic with the tester loop, can result in shifted and blurry images, making imaging as well as acquisition of IC voltage data difficult or impossible.

In addition, testing can depend on correlating a secondary electron signal with a position on a sample surface. The correlation provides information on regions of a sample, and, in turn, allows for the identification of specific devices being probed by a beam of electrons as a function of timing relative to a scan signal. In this way, EM interference during a test signal loop can degrade the accuracy of a given test. For example, where the EM interference induces a shift of the beam, the electrons making up the beam can probe a position on the surface of the sample that is different from the position indicated by the scan pattern. There is a need, therefore, for techniques and systems to identify, track, and correct beam shifts in scanning electron microscope images, for example, as part of an electron induced device alteration (EIDA) process.

### BRIEF SUMMARY

Aspects of the present disclosure include a method for localizing a defect in a sample. The method includes directing a beam of charged particles toward the sample. The method includes generating drift information for a drift of the beam of charged particles in one or more directions, the drift being induced at least in part by an electromagnetic field in a vicinity of the sample. The method also includes localizing a defect in the sample using the drift information.

In some embodiments of the method, generating drift information includes generating a sequence of images of the sample, wherein the sequence of images comprises a plurality of images of the sample and generating the drift information using the sequence of images. At least a subset of the images can describe a feature of the sample. Generating the drift information can include tracking the feature of the sample in the sequence of images and generating shift data describing a motion of the feature in the sequence of images. Localizing the defect can include generating location data describing a location of the defect in the sample using the sequence of images and pass/fail data for the sample. The drift information can include a drift vector, and localizing the defect can further include generating a correction vector using the drift vector and generating a scan signal of the beam of charged particles using the correction vector, such that the beam of charged particles is directed toward the location of the defect. The location data can describe a pass state or a fail state of a pixel of an image in the sequence of images.

In some embodiments of the method, localizing the defect in the sample includes identifying a defective device of the sample in reference to a map of the sample. The map of the sample can include a schematic description of the device. The defect can correspond to a fault in the device. The map can include computer-aided design data describing one or more devices of an integrated circuit.

In some embodiments, the electromagnetic field can be induced by a transient electrical signal applied to at least a portion of the sample. The sample can include a device under test (DUT). The transient signal can include a signal configured to operate the DUT at a pass-fail boundary, as part of a device perturbation test. The transient electrical signal can include a segment of periodic voltage. Localizing the defect can include implementing a binary search of a segment of the signal to identify a fault in the DUT.

Aspects of the present disclosure include a method for addressing beam drift artifacts in charged particle microscope images. The method can include determining an acquisition window making up at least part of an integrated circuit test loop. The acquisition window can include a time of interest (TOI) of the test loop. The method can include generating detector data for a charged particle microscope system, The detector data can describe a sample and can correspond to at least a portion of the acquisition window. The method can also include generating a deflection vector for the TOI. The deflection vector can describe a shift in a charged particle beam induced by an electromagnetic field in the vicinity of the charged particle beam.

In some embodiments, the method can further include identifying a position on the surface of a sample using the deflection vector. Identifying the position can include modifying the detector data using the deflection vector. The method can further include, on a pixel-wise basis, generating frequency information for the position on the surface using the detector data.

In some embodiments of the method, generating the deflection vector includes generating a sequence of images of the sample, wherein the sequence of images comprises a plurality of images of the sample and generating the deflection vector using the sequence of images. At least a subset of the images can describe a feature of the sample. Generating the deflection vector can further include tracking the feature of the sample in the sequence of images and generating shift data describing a motion of the feature in the sequence of images. The frequency information can describe an operating frequency of a device at the position. The detector data can include data for multiple points in time at the position. The method can further include generating waveform data using the detector data. The waveform data can describe an operating voltage of a device for the multiple time points.

In some embodiments of the method, the electromagnetic field can be generated by a transient electrical signal applied to at least a portion of the sample. The transient electrical signal can include a segment of periodic voltage.

Aspects of the present disclosure include a method for attenuating beam drift artifacts in charged particle microscope images. The method can include generating a sequence of images of a sample using a beam of charged particles. Electromagnetic interference can induce a drift of the beam of charged particles. The method can include generating drift information for the beam of charged particles in one or more directions using the sequence of images. The drift information can describe the drift of the beam induced by the electromagnetic interference. The method can include generating beam steering commands describing a correction of the drift of the beam. The method can also include modifying a scan pattern of the charged particle microscope using the beam steering commands.

In some embodiments, generating the sequence of images can include, on a pixel-wise basis, generating an image by incrementing a spot position of the beam across a surface of the sample and generating detector data for the spot position in coordination with a transient electrical signal being applied to at least a portion of the sample. Generating the sequence of images can include coordinating beam blanking circuitry of the charged particle microscope with a transient electrical signal, the beam blanking circuitry configured to block a portion of the beam and to produce one or more pulses of charged particles, and generating detector data while irradiating the current carrier with the one or more pulses of charged particles at the position, the detector data describing a timestep of the transient electrical signal.

In some embodiments, at least a subset of the images describe a feature of the sample. Generating the drift information can include tracking the feature of the sample in the sequence of images and generating shift data describing a motion of the feature in the sequence of images.

In some embodiments, the sample can include a device under test (DUT) and wherein at least a portion of the DUT is subjected to a transient electrical signal. The method can further include generating detector data using the modified scan pattern at a transistor or group of electronically coupled transistors of the DUT. The detector data can include secondary electron detector data. The method can further include generating frequency data over multiple time points of the transient electrical signal, using the detector data. The method can further include generating voltage data over multiple time points of the transient electrical signal, using the detector data. The method can further include generating waveform data for a given integrated circuit device of the sample using the voltage data. The method can further include generating timing data for an integrated circuit device of the sample using the modified beam scan pattern. The timing data can include a clock speed of the integrated circuit device.

Aspects of the present disclosure include a charged particle beam system, including a source of charged particles. The system can include computing circuitry, operatively coupled with the source of charged particles. The system can also include one or more media storing machine-readable instructions that, when executed by computing circuitry, cause the system to perform operations including those of one or more of the preceding aspects in various embodiments, alone or in combination.

The forthcoming description and the accompanying figures elaborate on the various technical features and attendant advantages of identifying, tracking, and/or correcting beam shifts in scanning electron microscope images, for example, as part of an electron induced device alteration (EIDA) process. In an illustrative example, a method for addressing beam drift artifacts in charged particle microscope images can include determining an acquisition window. The determination of the acquisition window can be based at least in part on a transient current signal making up at least part of an integrated circuit test loop. The acquisition window can include a time of interest (TOI) of the test loop. The method can include determining a deflection vector. The deflection vector can describe a characteristic shift in a charged particle beam induced by the periodic current signal during the acquisition window. The method can also include modifying a beam position on a surface of a device under test (DUT) using the deflection vector.

Methods of the present disclosure can include generating a sequence of images of a sample using a charged particle microscope. The sequence of images can include a plurality of images of the sample over a period of time separated by a period. The sample can include a current carrier that is generating transient electromagnetic interference. A method can include determining a drift of the beam in one or more directions using the sequence of images. The method can include generating beam steering commands describing a correction for the periodic drift of the beam. The method can include modifying a scan pattern of the charged particle microscope using the beam steering commands.

Methods of the present disclosure can include localizing a defect in a sample. A method can include directing a beam of charged particles toward the sample. The method can include generating drift information for a drift of the beam of charged particles in one or more directions. The drift can be induced at least in part by an electromagnetic field in a vicinity of the sample. The method can also include localizing a defect in the sample using the drift information.

The terms and expressions which have been employed are used as terms of description and not of limitation, and there is no intention in the use of such terms and expressions of excluding any equivalents of the features shown and described or portions thereof, but it is recognized that various modifications are possible within the scope of the claimed subject matter. Thus, it should be understood that although the present claimed subject matter has been specifically disclosed by embodiments and optional features, modification and variation of the concepts herein disclosed can be resorted to by those skilled in the art, and that such modifications and variations are considered to be within the scope of this disclosure as defined by the appended claims.

### BRIEF DESCRIPTION OF THE SEVERAL VIEWS OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram illustrating an example integrated circuit testing system, in accordance with some embodiments of the present disclosure.

FIG. 2 is a block flow diagram illustrating an example process for interrogating a device under test using a charged particle beam, in accordance with some embodiments of the present disclosure.

FIGS. 3A-3H are schematic diagrams illustrating an example sequence of images of a device under test, in accordance with some embodiments of the present disclosure.

FIGS. 4A-4C are graphs of example shift data and corresponding correction vectors in a cartesian coordinate space as generated from the image sequence of FIGS. 3A-3H, in accordance with some embodiments of the present disclosure.

FIGS. 5A-5C are graphs of example test signal data and corresponding shift vectors for a given time of interest (TOI), in accordance with some embodiments of the present disclosure.

FIGS. 6A-6C are schematic diagrams illustrating an example technique for perturbation of an integrated circuit device using a charged particle beam, in accordance with some embodiments of the present disclosure.

FIG. 7 is a schematic diagram illustrating an example technique for detecting defects in a device under test, in accordance with some embodiments of the present disclosure.

FIGS. 8A-8D are schematic diagrams illustrating an example technique for localizing a defect in a device under test in reference to a map of the device under test, in accordance with some embodiments of the present disclosure.

FIG. 9 is a block flow diagram illustrating data processing operations of an example technique for interrogating a device under test using a charged particle beam, in accordance with some embodiments of the present disclosure.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While illustrative embodiments have been illustrated and described, it will be appreciated that various changes can be made therein without departing from the spirit and scope of the disclosure. In the forthcoming paragraphs, embodiments of a charged particle beam system, components, and methods to identify, track, and/or correct beam shifts in scanning electron microscope images, for example, as part of an electron induced device alteration (EIDA) process. Embodiments of the present disclosure focus on scanning electron microscopy and related instruments (SEMs) in the interest of simplicity of description. To that end, embodiments are not limited to such instruments, but rather are contemplated for analytical instrument systems where analysis of a sample can be complicated by interference induced by electromagnetic fields in the vicinity of the sample. In an illustrative example, electromagnetic fields near or emanating from a sample can deflect or otherwise deform a beam of charged particles, such that imaging, precision, directing the beam to a desired position on the sample, and/or scanning the beam can benefit from the techniques of the present disclosure. The techniques of the present disclosure are contemplated to include applications in instruments including a transmission electron microscope (TEM), a scanning-transmission electron microscope (STEM), a STEM in SEM, an electron beam microanalysis instrument, and/or other instruments configured to generate image data from signals derived from the interaction of a sample with a beam of charged particles (e.g., ions or electrons).

Embodiments of the present disclosure improve the performance of charged particle beam systems during imaging and/or microanalysis, at least in part by permitting a system and/or user to account for the influence of electromagnetic interference on beam direction and/or shape. For example, accurately probing a sample including a nanostructured feature (e.g., an integrated circuit device such as a transistor) with an electron beam depends on precise positioning of the beam spot. In this way, electromagnetic fields that deform or deflect the beam can introduce error and adversely affect the accuracy of the probe technique.

The techniques described here can improve the quality and accuracy of charged particle microscope images and/or detector data generated during testing of a DUT (e.g., by imaging one or more regions of the DUT). Typically, an IC is exercised by a chip tester in a repeatable manner, where a test cycle is repeated in a loop including multiple iterations. Although the IC current consumption can change during different portions of the test loop, the current draw can repeat in a predictable manner between loops, corresponding to different times. Under test, ICs can generate electromagnetic interference that distorts the SEM imaging process. For example, magnetic fields created by currents within an IC can generate electromagnetic interference (EMI) that can deflect the beam of electrons used by the SEM to form images. In this way, unintended beam shifts can also repeat with each test loop.

Charged-particle beam techniques for assessing the performance of a DUT can be impaired by EM interference that deflects the beam. For example, such interference can significantly reduce the precision and accuracy of techniques that correlate spatial information (e.g., using beam scan data) with secondary electron detector data, such as electron beam perturbation techniques.

To that end, embodiments of the present disclosure include coordinating the imaging of a portion of the IC with a given portion of the test loop being run on the IC. For example, coordinating an imaging sequence (e.g., a beam scan pattern) with a segment of the periodic current signal permits beam shift to be coordinating with a time of interest of the test loop. Coordinating the imaging with the test loop permits the generation of static images of the IC. Without eliminating unintended beam shift, synchronizing the SEM imaging or voltage probing with a given portion of the test loop can reduce or eliminate the dynamic effects of current draw on beam shift, giving the images an appearance of temporal stability.

Methods of the present disclosure also include determining an extent of the beam shift at a given portion of the test loop. By coordinating the SEM imaging process with the tester loop that brings about unintended beam shifts, the beam shift at or about a time of interest within the testing loop can be determined. The beam shift extent can permit a probe beam to be accurately positioned on a device such as a transistor in the presence of a shifting beam, without interrupting or otherwise modifying the test loop.

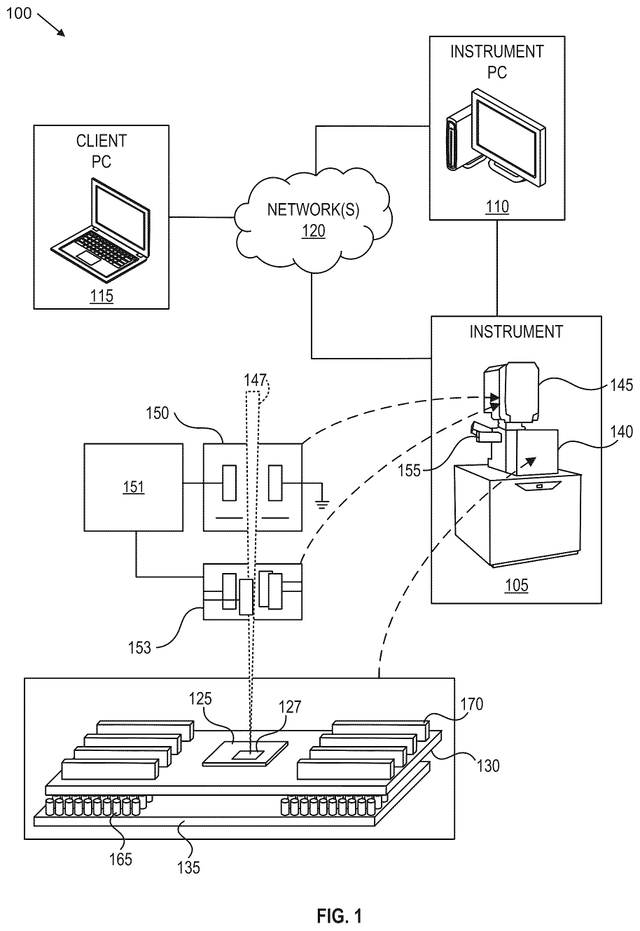

FIG. 1 is a schematic diagram illustrating an example integrated circuit testing system, in accordance with some embodiments of the present disclosure. The example system 100 includes an instrument 105, an instrument computing device (IPC) 110, and a client computing device 115, operably intercoupled via one or more networks 120. The example system 100 is configured to interrogate an IC device, termed a device under test (DUT) 125 using a test assembly 130 electronically coupled with components of the DUT 125 via a controller, also referred to as a test rig 135. Through application of time-varying electronic signals to components of the DUT 125, termed a “test loop” or “test pattern,” performance characteristics of circuit components of the DUT 125 can be derived as part of quality control and failure analysis techniques for ICs fabricated according to a given IC design.

The instrument 105 includes a test section 140 in which the test assembly 130 is disposed, including the DUT 125 as well as the electronic components to drive the test loop (e.g., the test rig 135), vacuum components to isolate the DUT 125 from atmosphere, and thermal management systems to remove heat from the DUT 125 during testing. Coupled with the test section 140 is a charged particle column 145. The charged particle column 145 can be an ion beam (e.g., focused ion beam (FIB)) column or an electron beam column (e.g., as part of a scanning electron microscope). In some embodiments, the instrument 105 includes a FIB column and an electron beam column with one of the charged particle sources being coupled with the test section 140 at an angle relative to the charged particle column 145.

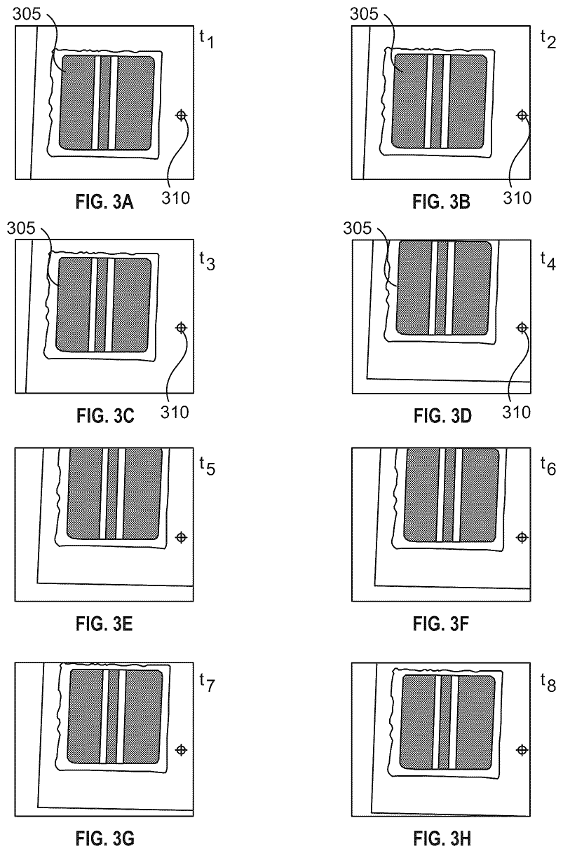

The charged particle column 145 can generate a beam of charged particles 147 and can focus the beam of charged particles 147 onto a region 127 of the DUT 125. The region 127 can include one or more conductive features, as described in more detail in reference to FIG. 3, that can be electrically active and inactive in accordance with one or more transient electrical signals applied to the DUT, also referred to as test pattern(s), test signal(s), test loop(s), or the like. The interaction of the beam of charged particles 147 with the DUT 125 gives rise to one or more detectable signals, which can be received by one or more detectors 155 operably coupled with the test section 140 and configured to generate detector data based at least in part on measurement of the signal(s). In an illustrative example, the detector(s) 155 can include secondary electron detectors, backscattered electron detectors, photon detectors, imaging sensors (e.g., CCDs) or the like. In contrast to a typical scanning electron microscope (SEM), the test section 140 can omit sample manipulation tools, such as an interlock, sample stage, and the like, at least in part because the DUT 125 can be removably coupled with the test assembly 130, which can be disposed on a stage, a cradle, or other retention assembly that provides electronic and thermal coupling with the test section 140 (e.g., coupled with the test rig 135). The beam of charged particles 147 can be directed toward the DUT 125 using various operational modes, including but not limited to imaging mode, line scan mode, spot mode, and/or pulsed mode.

To that end, the charged particle column 145 can include electronics and electron-optical components to manipulate the shape and/or direction of the beam of charged particles 147. For example, a beam blanker 150, disposed in the column can be configured to apply an electric field and/or a magnetic field across the path of the beam of charged particles 147. Control electronics 151, operably coupled with the beam blanker 150, can apply a time-variant voltage to an electrode of the beam blanker 150, such that an electric field can reversibly deflect the beam of charged particles 147 into a beam blocker. The operation of the beam blanker can permit the charged particle column 145 to direct pulses of charged particles toward the DUT 125. In some embodiments, a pulse includes as few as 1 charged particle to about 1000 charged particles, including physically meaningful fractions of the quoted range and sub-ranges thereof. For example, a pulse can include 3 charged particles, 5 charged particles, 10 charged particles, 15 charged particles, or the like. In some embodiments, a pulse can extend over multiple cycles of a test signal.

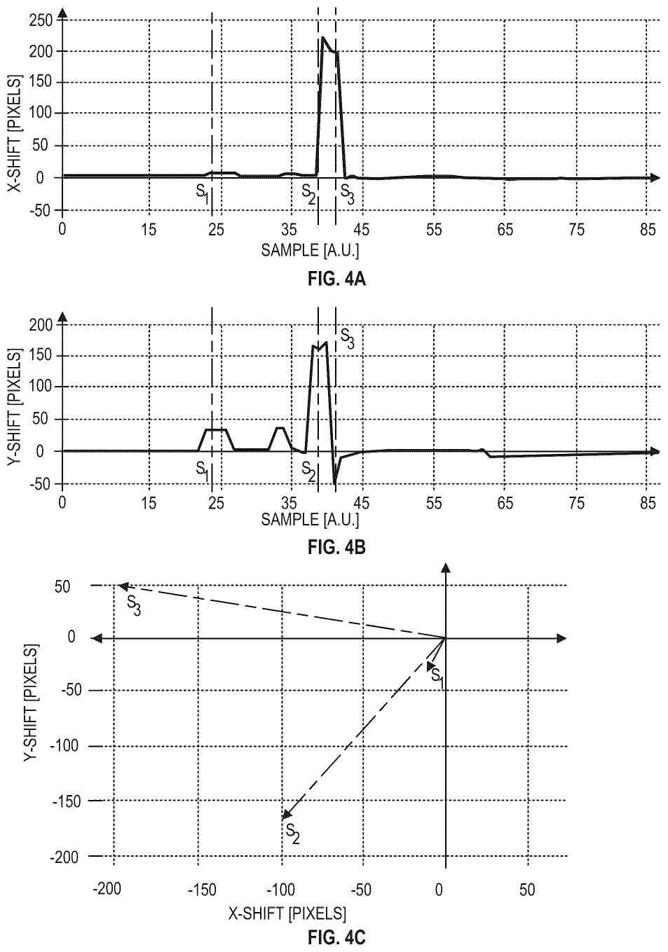

Charged particle column 145 can include one or more steering assemblies 153. The steering assembly 153 can include components configured to generate an asymmetric electromagnetic field. For example, an arrangement of steering elements (e.g., electromagnetic coils, electrostatic steering plates, etc.) can be operably coupled with the control electronics 151, configured to apply a voltage to one or more of the elements. The influence of the asymmetric field on the charged particles of the beam of charged particles 147 as they pass through the assembly 153 can controllably deflect the beam 147, as is typically done when generating image data in an SEM or other forms of detector data (e.g., in a STEM or SEM instrument). As described in more detail in reference to FIGS. 4A-7. In some embodiments, the steering assembly 153 is controlled by separate control circuitry from those used to control the beam blanker 150.

In some embodiments, the test assembly 130 is electronically coupled with components of the test section 140 via couplings 165, by which one or more test cards 170 can be driven. The test cards 170 can encode test loop protocols and can interface with the DUT 125 to input and output signals from the DUT 125 and to relay signals to other constituent elements of example system 100 (e.g., client PC 115 and/or IPC 110).

The computing devices 110 and 115 can be general-purpose machines (e.g., laptops, tablets, smartphones, servers, or the like) that are configured to operate or otherwise interact with the instrument 105. The instrument 105, in turn, can include electronic components that form part of a special purpose computing device, including control circuitry configured to drive the test loop, operate the test assembly 130, control the electron beam column 145, and operate the vacuum systems and thermal management systems. In an illustrative example, the test assembly 130 can be driven by a chip tester that runs independently from the instrument 105. The operation of the test assembly 130 can be coordinated with that of the instrument 105. For example, a chip tester can generate a trigger signal at the beginning of each test loop that is communicated to instrument 105. The instrument 105, in turn, can respond to the trigger signal at least in part by probing for a signal at a given position in the DUT. In another example, dedicated control electronics can be provided with the instrument 105 to coordinate operations of the instrument 105, such as those of the detector 155 and/or blanker 150, with the test assembly 130. The IPC 110 can be a machine provided with software configured to interface with the instrument 105 and to permit a user of the instrument 105 to conduct a test of the DUT 125. Similarly, the client pc 115 can be configured to control one or more systems of the instrument 105 (e.g., via the IPC 110 and/or by interfacing with the instrument 105 over the network(s) 120) to conduct a test of the DUT 125.

In some embodiments, the instrument 105, the IPC 110, and/or the client PC 115 are in separate physical locations and are coupled via the network(s) 120 and/or by other means, such as direct connection or by wireless connection (e.g., near-field radio). The network(s) 120 can include public networks (e.g., the internet) and/or private networks (e.g., intranet or local area networks). In some embodiments, the IPC 110 and/or the client PC 115 is/are configured to operate the instrument autonomously (e.g., without human intervention) or semi-autonomously (e.g., with limited human intervention, such as initiating a test, identifying a sample, and/or confirming an automated analytical result). In this way, the example system 100 can be configured to operate with human control and/or autonomously, as part of a scalable IC characterization system for automated testing of ICs.

The example system 100 can include additional and/or alternative components than those illustrated. For example, the instrument 105 can be operably coupled with one or more external components, such as signal generators, data acquisition systems, power supply systems, thermal management, or the like. Such components can be housed in cabinets, for example, that are physically separate from the instrument 105, but can be operably coupled with the charged particle column 145, the test section 140, the detectors 155, etc., by electrical and/or fluid-handling connections.

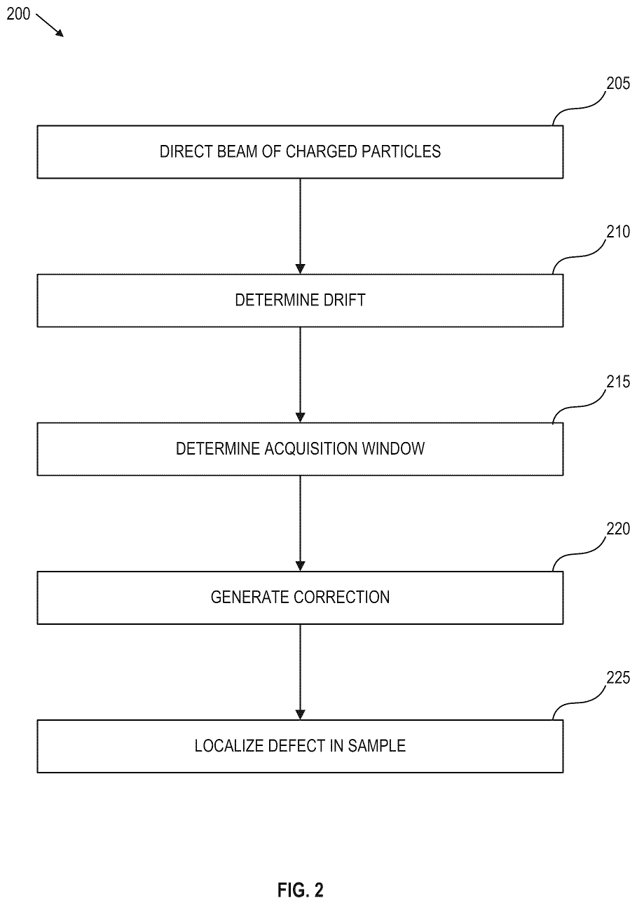

FIG. 2 is a block flow diagram illustrating an example process 200 for interrogating a device under test using a charged particle beam, in accordance with some embodiments of the present disclosure. One or more operations of the example process 200 can be executed by a computer system in communication with additional systems including, but not limited to, characterization systems, network infrastructure, databases, and user interface devices. In some embodiments, at least a subset of the operations described in reference to FIG. 2 are performed automatically (e.g., without human involvement) or pseudo-automatically (e.g., with human initiation or limited human intervention). In an illustrative example, operations for applying a test signal, directing a beam of charged particles toward the DUT (e.g., DUT 125 of FIG. 1), and generating detector data can be executed automatically, with the system (e.g., example system 100 of FIG. 1) being configured to generate visualization data showing one or more forms of output data for interpretation by a human user.

Embodiments of the present disclosure permit images to be generated during and/or throughout a tester loop (e.g., image(s) of a device under test (DUT) or regions of the DUT during and/or throughout the tester loop). A movie can be used to determine how the beam is deflecting during the tester loop, such that the deflection can be tracked and/or can be corrected. For example, correction can be implemented within scan control circuitry by providing offsetting corrections that are synchronized with the tester loop. In this way, an electron beam can be placed at a specific location on an active integrated circuit, and it will remain stationary at that location in the presence of perturbing fields created by the integrated circuit. Additionally or alternatively, correction can be implemented by applying an offset to detector data that accounts for the interference effect. While example process 200 is described as a sequence of operations, it is understood that at least some of the operations can be omitted, repeated, parallelized, combined and/or reordered. In some embodiments, additional operations precede and/or follow the operations of example process 200 that are omitted for clarity of explanation. For example, operations include those for calibration of the electron source, alignment and aberration correction of the beam of charged particles, introducing a DUT sample into the vacuum system, calibrating the system, or the like. In another example, a test pattern of time-variant voltage signals are applied to integrated circuit components, as part of determining one or more failure modes of the DUT (e.g., perturbation testing routines). In reference to example process 200, the operations of the instrument can be coordinated with those of the test assembly (e.g., test assembly 130 of FIG. 1), as part of generating data describing electrical activity of IC components of the DUT, from which defect information and/or other information can be derived.

At operation 205, the example process 200 includes directing a beam of charged particles toward a sample (e.g., DUT 125 of FIG. 1). As described in more detail in reference to FIG. 1, the beam of charged particles (e.g., beam of charged particles 147 of FIG. 1) can be a beam of electrons, but can otherwise include ions, neutral species, etc. Operation 205 can form a part of a broader procedure of imaging and/or microanalysis. Operation 205 can be part of an electronic failure analysis procedure used for quality control of semiconductor integrated circuits, as described in more detail in reference to FIG. 1. For example, operation 205 can be a part of frequency mapping, waveform collection, and/or electron-induced device alteration (EIDA) procedures. These specific examples are described in more detail in Examples 1-3, below, but are not intended to be limiting examples of applications of example process 200. To that end, operation 205 can include focusing the beam of charged particles onto a sample. Operation 205 can include pulsing or otherwise strobing the beam of charged particles. Finally, operation 205 can include operating in spot mode, with the beam being directed to a given position on the surface of a sample and held stationary for a given time; in line-scan mode, in which the beam is scanned in a linear pattern along the surface of the sample; and/or in image-scan mode, in which the beam is scanned in a two-dimensional pattern across the surface of the sample.

In some embodiments, one or more operations of example process 200 are repeated. For example operation 205 can be repeated multiple times as part of imaging a surface of a sample at a time of interest (TOI). In such cases, operation 205 can include directing the beam of charged particles toward a position on the sample surface in spot mode and holding the beam steady for one or more iterations of the test signal loop, during which detector data are generated. An image or other two-dimensional map (e.g., a frequency map and/or waveform map) can be generated by repeatedly generating detector data at an array of positions on the sample surface for the same TOI. Such an approach is achieved, at least in part, by strobing the beam of charged particles and coordinating the irradiation of the sample with pulses of charged particles with the TOI of the test signal. A time sequence of image frames can be generated by incrementing the TOI and repeating the sequence of measurements at the same or similar positions on the sample surface. In this way, the blurring and deflection of the beam of charged particles can be described with specificity as a function of TOI, in reference to the test signal, in a series of image frames.

At operation 210, the example process 200 includes determining a drift in one or more directions. As described in more detail in reference to FIGS. 3A-4C, drift can be determined using images of the sample generated during a test loop. Motion of one or more features of a sample surface, such as edges or other trackable aspects of a sample can be used to generate deflection data as a function of sample number. Sample number, in turn, can be correlated to an increment, interval, time, timestep, or the like, in the test signal, from which a deflection for a time of interest (TOI) can be determined.

In some embodiments, where an acquisition window and/or TOI is described or otherwise known (e.g., provided by an external client in communication with the system or the user), the deflection parameters for the beam of charged particles can be determined for the specific TOI or within the acquisition window, using the corresponding image frames generated by coordinating the operation of the charged particle beam instrument with the test signal (e.g., through signal-locking). The selection of image frames can be based at least in part on information derived from the test signal. For example, where the test signal includes a time-variant voltage component and/or a time-variant current component (e.g., described in terms of power as a function of time) the image generated in the absence or relative absence of EMI can be selected from detector data corresponding to a time at which the power, or one of its components, is relatively low (e.g., below a threshold value) such that the image can serve as a reference state. Similarly, the image generated in the presence or relative presence of EMI can be selected from detector data corresponding to a time at which the power, or one of its components is relatively high.

In an illustrative example of the technique in a circuit device, a rectangular printed circuit board, of length L and width W, was covered with conducting copper, through which a current “I” was passed. The current was characterized by a 1 Amp square wave. In the absence of current flowing on the surface of the printed circuit board, the electron beam was applied to generate a first contamination spot. In the presence of a current along the length of the rectangular printed circuit board, a magnetic field was induced that deflected the incoming electron beam path and resulted in a shift in the beam spot position in two spatial directions on the surface of the circuit board (e.g., “x-y” coordinates). A second contamination spot was generated with current flowing and the distance from the first contamination spot was determined to be approximately 900 nm, representing the spatial magnitude of a deflection vector. Further, the angle relative to a reference axis was determined, from which a deflection vector was determined. Reversing the direction of the current results in an equivalent reversal in the beam shift direction (e.g., corresponding to the inversion of polarity of the induced magnetic field). Switching the current direction in a periodic manner results in periodic shifting of the image, which introduces a blur artifact into the image. A series of images at 1 microsecond spacing was generated during the current switching period.

In some embodiments, a deflection vector can be determined without generating contamination of a sample surface. One or more images can be generated in the absence of EMI, one or more images can be generated in the presence of EMI, and various image processing techniques can be applied to determine a deflection vector. For example, one or more features that are present in the images can be tracked to generate a deflection vector. Similarly, image convolution techniques can be used to generate a deflection vector, using an image generated in the absence or relative absence of EMI and an image generated in the presence or relative presence of EMI. The convolution algorithms can be agnostic to parameters of the DUT tester loop, for example, where the image frequency is known. In some embodiments, a fiducial or other marker can be tracked, the motion of which can be used to determine a deflection vector.

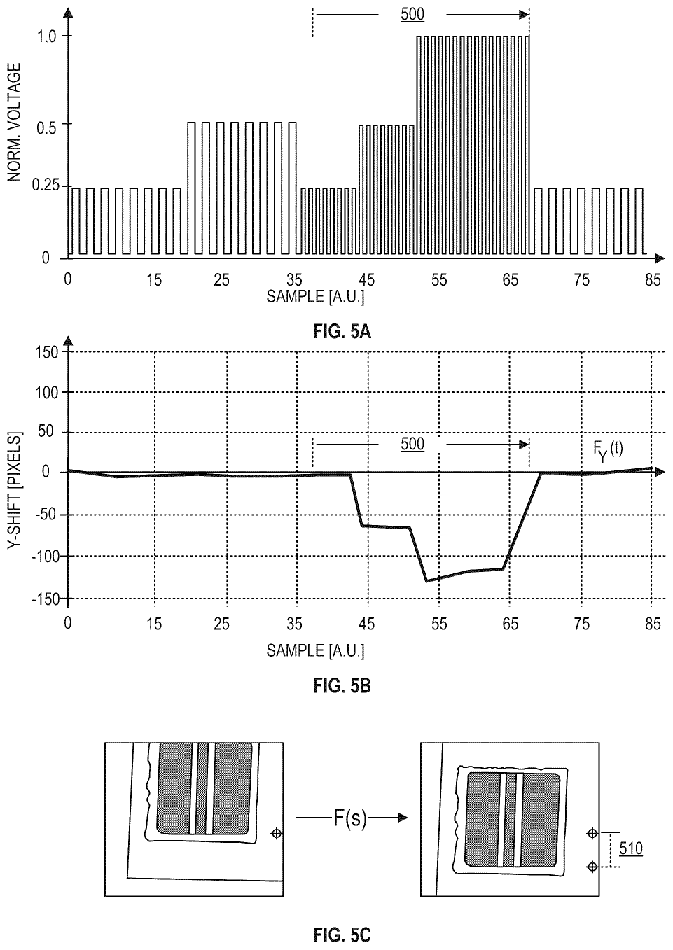

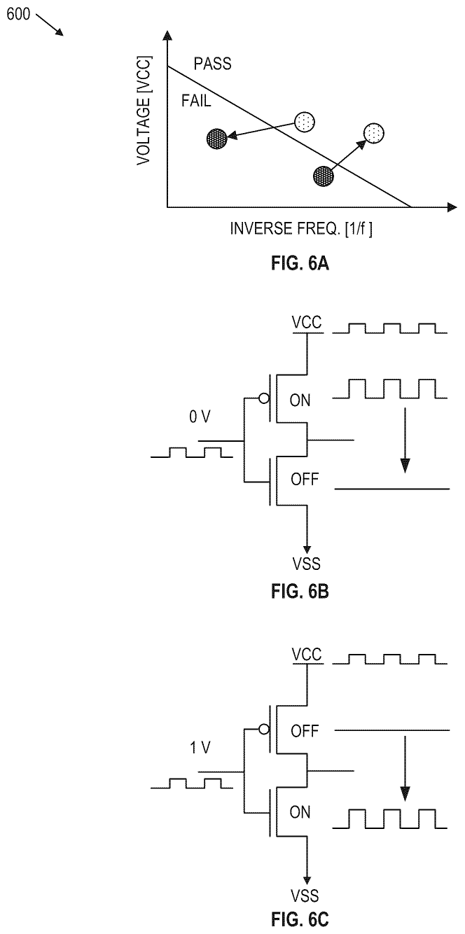

At operation 215, the example process 200 includes determining an acquisition window. When voltage probing data is to be acquired from a given location on the IC at a TOI within a test pattern, image acquisition can be coordinated with the test pattern such that image data is collected during an acquisition window including the TOI (e.g., centered around the TOI). As described in more detail in reference to FIGS. 5A-5C, coordination of imaging and test pattern can include strobing or otherwise pulsing the beam of charged particles (e.g., beam of charged particles 147 being blanked by beam blanker 150 of FIG. 1).

Where the duration of the acquisition window is relatively short, beam shift during imaging can be reduced or negligible and an image of the device with minimal distortion can be produced. Images generated during the acquisition window can be used to determine beam placement for voltage probing of the IC, an example of which is described in reference to defect localization, described in FIGS. 6A-8D.

To that end, extents, magnitudes, or other parameters of unintended beam shifts that occur periodically in time (“t”) or a-periodically (e.g., in accordance with an aperiodic test signal) can be determined in a given coordinate system (e.g., cartesian “x” and “y” coordinates). With such parameters, systems can counteract the unintended beam shifts using offsetting signals generated within scan control logic. Described as an algorithm, a process can include operations for determining x(t) and y(t), where 0≤t≤T₀, where x(t) and y(t) describe the beam shift at time t, in the x and y scan direction respectively, due to an external perturbing electromagnetic field that is periodic with period T₀. In relation to the embodiments described with reference to the deflection vector, above, x(t) and y(t) can be components of a time-variant deflection vector r(t), x(t), y(t), r(t), etc., As described in more detail in reference to FIGS. 4A-4B. Spatial variation of EMI over the length-scale of the surface under examination can be such that x(t), y(t), and/or r(t) are uniform over the surface of a region of interest (ROI) (e.g., region 127 of FIG. 1). As such, a beam deflection can be consistent across an image, line-scan, and/or sampled positions on the surface of the ROI.

In some embodiments, the IC can be covered by a metal heat spreader plate through which a hole can be formed to give access to the DUT for e-beam imaging and/or processing. Experimental data indicate that the skin depth of the metal cover plate can effectively shield high-frequency magnetic field variations coming from DUT currents. In this way, high-frequency effects can be limited, with low-frequency magnetic field variations affecting the SEM beam. Advantageously, the acquisition window including the TOI for imaging or probing of such shielded DUTs is prolonged relative to unshielded DUTs, owing the relatively attenuated high-frequency EMI effects.

At operation 220, the example process 200 includes generating corrected detector data. Corrected detector data generally describes images of a sample surface, frequency information (e.g., an operating frequency of a device at a given position in the DUT), waveform information (e.g., a sampled frequency, voltage, or other signal over time for a given device), device state information, timing data, etc. for which the effect of EMI has been attenuated or removed by accounting, at least in part, for EMI-induced beam drift. In one example, using the deflection vector, a correction can be applied to accurately position a beam of charged particles (e.g., an electron beam, an ion beam, a beam of neutrals, etc.) for imaging and/or probing on a given structure, surface, material, etc. on the DUT, as described in reference to operation 205, above. In another example, timing data can include a clock speed of at least part of the DUT.

Deflection information can be used to generate offsetting beam steering commands that reduce or eliminate known periodic interference in an SEM imaging system.

Advantageously, systems can be configured to offset known periodic unintended beam shifts. SEM images that would otherwise be blurred due to periodic beam shifts can be collected absent the effects of such interference. The beam of the SEM system can be trained on a device at a given position or ROI in the presence of external interference (e.g., coming from the device itself) that acts on the beam to deflect the beam away from the position or ROI. In this way, a process for correcting EMI effects on charged particle microscopy can include modifying beam steering logic to correct for x(t) and y(t) (e.g., updating beam steering commands) to counteract the unintended beam shift induced by the perturbing electromagnetic field. With the interference induced by the perturbing fields counteracted, the process can include generating secondary electron images, waveform data, device state data, and/or frequency data with reduced or negligible interference artifacts (e.g., the periodic interference having been removed from the measurement) and/or voltage probing without interrupting the test loop.

Attenuating the beam shift artifacts can include inserting time-variant offsetting beam shifts into an SEM image scan or point-mode beam signal. For example, a predefined scan cycle can be modified to accommodate the beam shifts. Advantageously, the techniques described herein counteract unintended beam shifts as the images are generated, and with relatively little or no latency, resulting in stationary images substantially free of image blur from unintended beam shifts and/or stable voltage signals substantially free of noise caused by time-variant EMI.

Embodiments of the present disclosure also permit a charged particle systems to correct for periodic EMI perturbation from ambient and/or external sources. Examples include, but are not limited to correcting for 50- and 60-Hz line interference, allowing images to be collected without regard to aligning data collection with the 50- or 60-Hz line rates. In this way, techniques described herein can be applied to periodic EMI signals that interfere with STEM, SEM, or FIB imaging, more generally. In an illustrative example, SEM image artifacts that are caused by an active integrated circuit (e.g., the DUT) that is drawing electrical power, creating magnetic fields, can be corrected.

At operation 225, the example process 200 includes localizing a defect in the sample. As described in more detail in reference to Example 1, below, localizing the defect in the sample can include one or more sub-operations for detecting, identifying, and/or mapping a fault in the sample to a schematic or other representation of an integrated circuit. In Example 1, this technique is termed “Electron-Induced Device Alteration,” (EIDA) analogous to Laser-Assisted Device Alteration (LADA), albeit at significantly improved spatial resolution. A disadvantage of the EIDA technique relative to the LADA technique is the sensitivity of electrons to EMI. Without the techniques of the present disclosure, EMI during testing substantially eliminates the spatial resolution gain of EIDA relative to LADA.

FIGS. 3A-3H are schematic diagrams illustrating an example sequence of images of a device under test (DUT), in accordance with some embodiments of the present disclosure. The diagrams represent a microelectronic device 305, such as an integrated circuit device or assembly of devices, as imaged using a scanning electron microscope. The example sequence, labeled with timestamp references t₁ through t₈, does not correspond to a particular frame rate. Instead, the figures making up the example sequence illustrate the influence that electromagnetic (EM) interference can exert on a beam of charged particles (e.g., the beam of charged particles 147 of FIG. 1), at least in part by deflecting the beam, resulting in a shift of the secondary electron image generated from the interaction of the beam and the device 305. For a transient electromagnetic field, t₁-t₈ can correspond to a time on the order of tens of nanoseconds, hundreds of nanoseconds, microseconds or longer, based at least in part on dynamics of the beam, detector hardware, etc.

The image shown in FIG. 3A represents an undisturbed state of the DUT, labeled t1, where the device 305 is substantially centered in the frame. The image includes a reference marking 310 that can be associated with a given pixel in the detector or other reference that is stationary relative to the image of the surface. The relative motion of the device 305 and/or other features of the image, as compared to the reference marking 310, can be used to generate shift information, as described in more detail in reference to FIG. 2 and FIGS. 4A-5C.

The FIGS. 3B-3H illustrate the reversible influence of electromagnetic interference on secondary electron image data, where the image of the device 305 shifts in vertical (“y”) and lateral (“x”) dimensions in response to a transient electromagnetic field in the vicinity of the sample. The shift is visually intuitive, being demonstrated by the movement of the device 305 partially out of frame of the image in FIGS. 3D-3F, moving back into frame in FIG. 3G. FIG. 3H illustrates the continued relaxation of the beam back toward the undisturbed state of t₁ in FIG. 3A.

Periodic test signals can induce a repeated shift like the one illustrated in FIGS. 3A-3H. Where the frequency of the test signal, or the time between pulses in an aperiodic signal, is shorter than the characteristic relaxation time of the beam of charged particles, over which the beam of charged particles is at least partially deflected, the detector data can include both a shift in x-y coordinates and a blur. The blur can be attributed, at least in part, to the repeated partial relaxation of the beam between the initial state and a deflected state. In some cases, the blur can be based at least in part on the oscillation of EMI at a timescale shorter than the bandwidth of the detector used to generate the sequence of images.

FIGS. 4A-4C are graphs of example shift data and corresponding correction vectors in a cartesian coordinate space as generated from a sequence of secondary electron images (e.g., the image sequence of FIGS. 3A-3H), in accordance with some embodiments of the present disclosure. As described in more detail in reference to FIGS. 1-2 and FIGS. 5A-5C, coordinating the pulsing of the beam of charged particles with the test signal can permit a shift vector to be determined and used to account for and/or correct for the interference effect of EMI on the beam of charged particles and detector data. In reference to the sequence of images in FIG. 3A-3H, a pulsed-beam approach permits a single state (e.g., from among t₁-t₈) to be sampled. The three labeled states S₁-S₃ correspond to sampled states for which the shift data in FIGS. 4A and 4B are used to generate the corresponding correction vectors in FIG. 4C.

Generating image data can include coordinating a pixel clock to the test loop signal (e.g., synchronizing the pixel clock with a start trigger of the test loop). In this way, detector data can be generated in a pixel-wise fashion, by which the beam dwells at each pixel in a frame for one or more loops of the test pattern. This approach can be implemented using a pulsed beam (e.g., to sample the test loop) or using an un-pulsed beam (e.g., generating data at the detector bandwidth). Where the detector bandwidth has a lower bandwidth than the test pattern, this approach can be understood to sample the test loop signal as well. This approach has the advantage of being faster than using a pulsed beam for acquisition of image data for a single pixel. For example, a pulsed approach involves sampling a point in time across multiple loops of a test pattern, making the generation of a single image a geometric function of the number of pixels and the number of time points. In this way, using an unpulsed beam permits a frames to be generated in the same length of time used to capture a single frame by pulsing once per test loop per pixel. Sub-sampling can be used to reduce charging effects caused by pixel dwell time. For example, two images can be generated using an unpulsed beam with a dwell time of half the length of a test pattern, by starting at different pixels (e.g., neighboring pixels).

The data shown in FIGS. 4A-4B correspond to a sequence of images (sample number) from which x-y shift information (in pixels in the x- and y-dimensions, respectively) is generated. As described in more detail in reference to FIG. 2 and FIGS. 3A-3H, shift information can be generated using various image processing techniques, including feature tracking, by which the motion of one or more visual aspects of a sample can be determined. The shift data, shown in reference to cartesian x-y coordinates, can be projected into additional or alternative coordinate spaces. For imaging data, an x-y coordinate space is an effective and intuitive approach for characterizing shift over a sequence of images.

FIG. 4C illustrates that a correction vector for a given state, Sᵢ, can be determined using the individual contributions in each of “n” dimensions (e.g., x- and y- for two dimensional cartesian space) as components of an n-space vector. The shift vector, describing the magnitude of the deflection of the beam for a given state, and a correction vector, describing the magnitude of the correction used to attenuate the deflection of the beam, are opposites (e.g., the dot product of the two vectors is zero). As such, the correction vector can be determined by element-wise multiplication of the shift vector for a given state by negative one (−1).

As described in more detail in reference to FIG. 2, the correction vector can be used by control circuitry (e.g., control circuitry 151 of FIG. 1) to modify the scan pattern of the beam of charged particles. In this way, the shift can be countered and even eliminated. As described in more detail in reference to FIGS. 5A-5C, one or more states can be used as part of imaging, frequency mapping, and/or waveform measurement, among other failure analysis techniques, based at least in part on measuring one or more positions of a sample over multiple iterations of a test signal. In an illustrative example, where a TOI is specified (e.g., relative to a start trigger of a test signal), a pulsed beam of charged particles can be coordinated with the test signal such that the same point in the test signal is repeatedly sampled, while the beam of charged particles and/or the detector data are offset to correct for EMI. The collected information can be used to assemble a sequence of images of the sample at different TOI values. This is in contrast to scanning the beam across the sample to collect image data, as is typically done in SEM/STEM applications, due at least in part to the dynamics of the test signal being faster than the response time of the beam scanning optics.

FIGS. 5A-5C are graphs of example test signal data, a corresponding shift vector, and a corrected image for a given time of interest (TOI), in accordance with some embodiments of the present disclosure. The data in FIGS. 5A-5B are shown in sampled-time, such that the x-axes of FIGS. 5A-5B are in arbitrary units. Advantageously, sampled-time illustrates the applicability of techniques of the present disclosure to different time-scales. For example, the typical time scale for a single loop of a DUT test signal is on the order of microseconds to on the order of milliseconds to tens of milliseconds. In some embodiments, a lower limit of test loop duration corresponds to a loop frequency of about 500 kHz, or about 2 microseconds. The frequency of the test pattern signal, however, can be on the order of GHz, making down-sampling a helpful approach to reduce data volume and to address bandwidth limitations in column, detector, and signal processing hardware (e.g., of instrument system 100 of FIG. 1). In some embodiments, signal processing electronics and detector components are provided that have bandwidth wide enough to process unsampled data (e.g., substantially equal volumes of detector data and DUT voltage data).

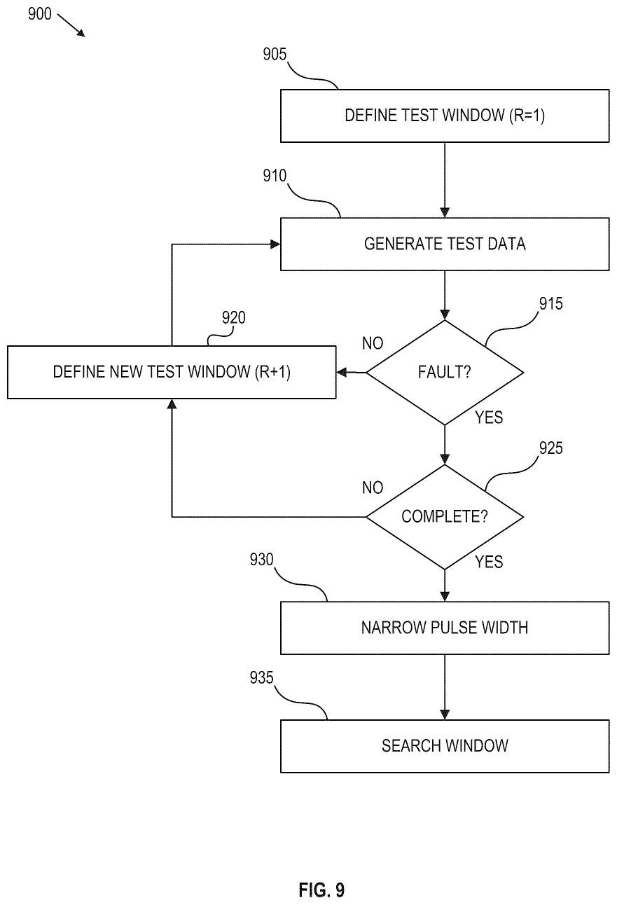

An acquisition window 500 can be defined within which detector data are used to determine shift information, as described in more detail in reference to FIGS. 2-4C. In some embodiments, the acquisition window 500 is received from a client system (e.g., as an input parameter. In some cases, however, the position and duration of the acquisition window 500 can be determined as part of a test procedure, as described in more detail in reference to operation 215 of FIG. 2. A search of the acquisition window 500 can be undertaken to identify and/or localize faults in the DUT, for example, by a binary tree search as described in reference to Example 2 and FIG. 9.

The acquisition window 500 can be defined such that a measurement procedure includes a TOI or multiple TOIs. In this way, performance of the DUT can be analyzed at the TOI(s) with substantially no EMI effect on the detector data and on the probing performance of the charged particle beam. For example, shift data and correction data generated for the acquisition window 500 can permit the derivation of a transfer function F(s) to be applied to the steering circuitry and/or secondary electron detector data for a given state or states (e.g., an offset to the scan signal to account for the effect of EMI at a given TOI). Where the transfer function is applied to data generated without correction of the scan signal, detector information can be preserved, shifting the reference marking by a state-dependent offset 510 along with the detector data (e.g., the offset 510 can vary with sampled-time and/or relative position in the test signal).

### EXAMPLE 1: ELECTRON INDUCED DEVICE ALTERATION

FIGS. 6A-6C are schematic diagrams illustrating an example technique for perturbation of an integrated circuit device using a charged particle beam, in accordance with some embodiments of the present disclosure. Leveraging the spatial resolution of charged particle beams, individual devices (e.g., transistors) and small groups of transistors can be modulated between a pass-state and a fail-state at least in part by injecting charge from the beam. In FIG. 6A, a graph of pass-fail data is shown on paired axes representing inverse frequency on the horizontal axis against common voltage Vcc on the vertical axis. The inverse frequency is a dependent variable in this example data, in that the frequency is determined by the test signal at a given TOI. The test signal can be a transient electrical signal that includes at least a segment of periodic voltage alternation (e.g., an AC signal, a square-wave signal, etc.).

The voltage can be modulated while the device is irradiated by the beam of charged particles (e.g., the e-beam) to move a device from a pass state (hollow circle, “∘”) to a fail state (filled circle, “•”) or vice versa. In some cases, the frequency can also be varied, for example, as an approach to determining at what point of a test loop a given device fails. The setup for EIDA analysis involves connecting the device to a test stimulus, as described in more detail in reference to FIG. 1. The test parameters for operating voltage and device speed are then adjusted to place the DUT into a state which borders on a pass-fail or fail-pass transition. It is useful to use a tester Shmoo plot to select the appropriate operating conditions. The effect of irradiating individual devices in the DUT is to trip a given device from a pass into a fail condition, or from a fail into a pass condition. The result of the transition can be measured by the test system as changes in the output signals from the DUT.

FIGS. 6B-6C illustrate example circuit diagrams showing coupled PMOS and NMOS transistors in an exemplary CMOS inverter logic gate circuit. Charge injection by the charged particle beam has differing effects on NMOS and PMOS transistors. In the case of NMOS, the transistor will change states from “off” to “on.” For PMOS, however, the effect is to lower the transistor threshold voltage. The effect on the PMOS transistor becomes proportionately stronger as the level of charge injection is increased (e.g., proportional to beam current). The effect is to either increase or decrease the speed of the device being tested. This makes EID A a suitable technique for determining critical timing paths within a semiconductor circuit. In the examples of FIGS. 6B-6C, an e-beam will cause the device to switch from a pass state to a fail state in the case of FIG. 6B, and from a fail state to a pass state in the case of FIG. 6C.

The reliance of the EIDA technique on spatial resolution to alter the function of specific transistor(s) within an integrated circuit, demonstrates the importance of 1) spatial location information of transistor(s) in a sample; 2) accurate positioning of a beam spot on the transistor(s); and 3) stability of the beam under the influence of EMI during a test loop. Advantageously, the techniques described herein permit EIDA to be performed with substantially reduced or negligible impairment by EMI.

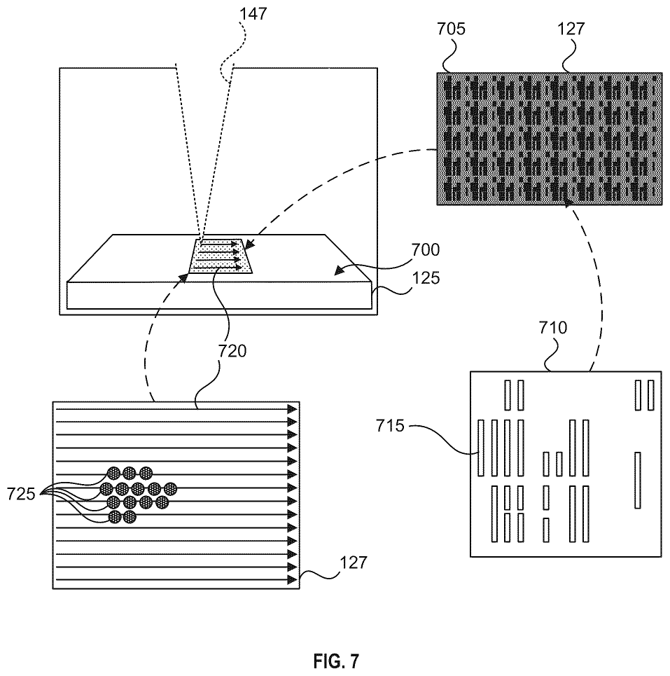

FIG. 7 is a schematic diagram illustrating an example technique for detecting defects in a device under test (e.g., DUT 125), in accordance with some embodiments of the present disclosure. A surface 700 of the DUT 125 has a region exposed 705 to irradiation by a beam of charged particles 147 (e.g., beam of charged particles 147 of FIG. 1). The beam 147 is used for a pass/fail analysis of circuits 710 of transistor devices 715 making up the DUT 125. By irradiating the surface 700 in a pixel-wise approach 720 at multiple positions on the surface (e.g., in a line-scan approach, taking measurements at multiple positions along the line), as described in more detail in reference to FIG. 2, defective devices can be identified and localized on the surface 700 with improved precision as compared to laser-based techniques (LADA) and electron-based techniques for which EMI effects are not controlled.

In an illustrative example, fail determinations are made for locations 725 of the region 705. The determinations may be made based on analysis of a resulting response, such as plot of a pass/fail analysis indicating a FAIL and/or a PASS, as described in more detail in reference to FIGS. 6A-C. In device perturbation (DP) the DUT 125 can be placed at the boundary of pass and fail (e.g., at specific temperature, voltage or frequency) and an electron beam can be used for device perturbation. In an example of the technique, the electron beam is scanned over the region 705 (e.g., in a raster pattern) while the chip is operated at a pass/fail boundary condition. When the electron beam hits a device and changes the chip from passing to fail (or vis versa), the location of the marginal device is recorded in location data. The location data can be generated using scan information, detector data, and/or DUT output data. Correlating the position of the beam (e.g., in the scan pattern) with pass-fail data, a relative position in the scan pattern can be determined (e.g., in fractional time, etc.), which can be correlated, in turn, with a position on the surface of the DUT 125 (e.g., in reference to a point on the surface or other spatial registration marking).

In some embodiments, an electron beam is scanned over the region 705 and the resulting detector data and DUT 125 output information are used for mapping (e.g., by electron-beam signal image mapping, or ESIM, or e-beam logic state imaging, or ELSI). As described in reference to FIG. 2, such data can be generated on a pixel-wise basis (e.g., scanned stepwise at multiple mutually resolved points), while a test signal is repeated and the DUT 125 is operated at the pass-fail boundary. Where the test pattern loop is coordinated with electron pulses (e.g., using a beam-blanker as described in reference to FIG. 1) the DP technique can include monitoring pass-fail and/or fail-pass transitions of the DUT 125 (e.g., as a function of timestep in the test signal). For non-destructive measurements, the electron beam can have an energy below a threshold energy for altering the structure of the DUT 125, which can be a material-dependent and parameter dependent threshold (e.g., beam-current as well as beam energy).

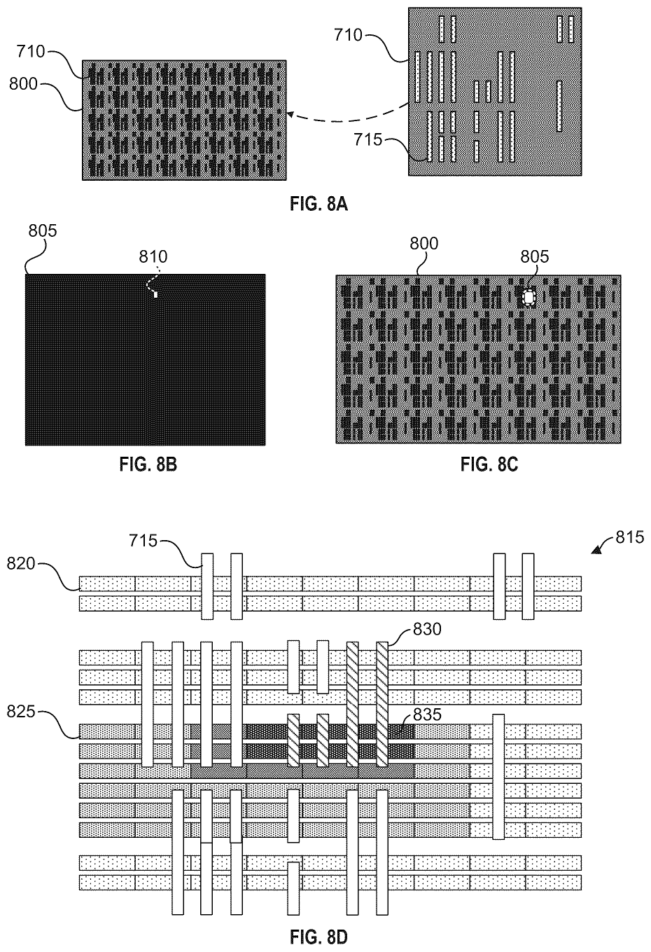

The DP approach permits an SEM image to be correlated with an defect map through coordinating the beam steering signal with the output signal of the DUT 125. A compound image can generated to illustrate locations of defective devices, critical timing devices, or other features of the DUT 125 that are of interest for failure analysis and timing analysis. Where a resolution of approximately 5 nanometers can be achieved in the absence of EMI, EMI significantly impairs the performance of typical DP. To that end, techniques of present disclosure permit DP data to be generated with resolution at the device scale, as described in more detail in reference to FIGS. 8A-8D.

FIGS. 8A-8D are schematic diagrams illustrating an example technique for localizing a defect in a device under test (DUT) in reference to a map of the DUT, in accordance with some embodiments of the present disclosure. Techniques of the present disclosure include coordinating spatial information, DUT pass-fail and/or timing data, and imaging data as part of functionally localizing failure analysis and/or timing data to one or more devices. As described in more detail in reference to FIGS. 2-5C, EMI impairs the localization of spatial information derived from the interaction of the beam of charged particles with devices of the DUT. Deflection and deformation of the beam affects imaging, failure analysis, timing analysis, and waveform/frequency measurement. Correction of the influence of EMI on the direction and/or shape of the beam permits EIDA techniques to be used to correlate DUT schematic/map information with the DP information described in reference to FIG. 7.

As illustrated in FIG. 8A, secondary electron image data 800 of the region 705 of the DUT 125 that is used for DP analysis can include detailed information showing one or more devices 715 (e.g., fins, transistors, etc.) that can be modified and/or whose operation can be altered by the charged particles of the beam. The secondary electron image data 800 can be correlated to DP data 805 at least in part by generating an array correlating the DP data 805 to secondary electron image data 800, for example, as a binary mask where each pixel (or a subset of the pixels) of the secondary electron image data 800 is associated with a true value 810 (e.g., value=1) where a state transition occurs (e.g., from pass to fail or vice versa) and a false value (e.g., value=0) where a state transition doesn't occur. An example of the binary mask approach is shown in FIG. 8B.

Coordinating (e.g., superimposing, convoluting, etc.) the DP data 805 with the secondary electron image data 800 permits a spatially resolved map of measurement information to be generated. In the example of FIG. 8C, the region of the secondary electron image data 800 corresponding to the true values 810 of the DP data 805 is occluded as a visually intuitive approach for identifying regions of the DUT 125 that are defective. The secondary electron data 805, in turn, can be mapped onto schematic information, such as CAD data or other design specifications for the DUT 125, such that the DP data 805 can be correlated with the map of the DUT 125, an example of which is illustrated in FIG. 8D.

FIG. 8D represents the DP data 805 as a binned “heat map” 815 of shaded cells with a lighter shade 820 representing a smaller DP signal and a darker shade 825 representing a stronger DP signal. Correlation of DP heat map 815 data with accurate and precise spatial information, derived from the EMI-corrected SEM beam position, permits one or more defective devices 830 to be identified from amongst the devices 715 in the circuit(s) 710. In an illustrative embodiment, heat map 815 cells above a given value 835 (e.g., where fault density as a function of surface area is above a threshold value) can be associated with faults in the DUT. Localizing a defective device 830 in the sample, therefore, can include identifying devices 710 that are at a position of relatively high fault density. Understandably, the success of EIDA techniques depend at least in part on accurate spatial information for secondary electron data 800, DP data 805 and schematic information. Accurate positioning of each data type depends, in turn, on accurate information about the beam spot position on the surface of the DUT 125. The variable and unpredictable effects of EMI on beam spot position presents significant challenges to accurate and precise spatial correlation of the different data types, making EIDA and other techniques described herein impractical. Advantageously, identifying, tracking, accounting for, and/or correcting the effect(s) of EMI on the beam can resolve the challenges of accurate and precise localization of faults or other characterization/analysis of the DUT 125.

In the illustration of FIG. 8D, the defective device(s) 830 are diagonally-hatched. In some embodiments, the schematic diagram of FIG. 8D can be represented in visualization data formatted to be presented on a computer display (e.g., using IPC 110 and/or client computing device 115). To that end, processes and methods of the present disclosure include generating visualization data including at least a portion of the information depicted in FIG. 8D. For example, the visualization data can include CAD data including labels indicating the defective device(s) 830. In some cases, the visualization data includes the CAD data superimposed on the secondary electron image data 800 (e.g., formatted for viewing in an image viewing application).

### EXAMPLE 2: SEARCH TECHNIQUES

FIG. 9 is a block flow diagram illustrating an example process 900 for interrogating a device under test using a charged particle beam, in accordance with some embodiments of the present disclosure. One or more operations of the example process 900 can be executed by a computer system in communication with additional systems including, but not limited to, characterization systems, network infrastructure, databases, and user interface devices. In some embodiments, at least a subset of the operations described in reference to FIG. 9 are performed automatically (e.g., without human involvement) or pseudo-automatically (e.g., with human initiation or limited human intervention). In an illustrative example, operations for defining a test window, directing a beam of charged particles toward a DUT (e.g., DUT 125 of FIG. 1), and generating detector data can be executed automatically, with the system (e.g., example system 100 of FIG. 1) being configured to generate visualization data showing one or more forms of output data for interpretation by a human user.

While example process 900 is described as a sequence of operations, it is understood that at least some of the operations can be omitted, repeated, parallelized, combined and/or reordered. In some embodiments, additional operations precede and/or follow the operations of example process 900 that are omitted for clarity of explanation. For example, operations include those for calibration of the electron source, alignment and aberration correction of the beam of charged particles, introducing a DUT sample into the vacuum system, calibrating the system, or the like. In another example, a test pattern of time-variant voltage signals is applied to integrated circuit components, as part of determining one or more failure modes of the DUT (e.g., perturbation testing routines). In reference to example process 900, the operations of the instrument can be coordinated with those of the test assembly (e.g., test assembly 130 of FIG. 1), as part of generating data describing electrical activity of IC components of the DUT, from which defect information and/or other information can be derived.

The constituent operations of example process 900 are described using an exemplary binary search algorithm, by which a Time of Interest (TOI) can be identified. In some embodiments, however, additional and/or alternative search algorithms are applied. For example, the binary search can be complimented and/or replaced by an interpolation search, an exponential search, a ternary search, section search, or the like. In this way, the TOI for a given signal can be used to isolate a fault using the test signal output from the DUT. Coordinating the operation of the charged particle beam system with the DUT test signal output permits systems of the present disclosure to localize defects in the DUT. Advantageously, the techniques for tracking and/or correcting EM-induced beam deflection and/or distortion, as described in more detail in reference to the preceding figures, (e.g., FIG. 2), permit the precise and accurate association of temporal information (e.g., fault timing information) with spatial information (e.g., beam spot position).

At operation 905, example process 900 includes defining a test window. A test window describes a portion of the test pattern (e.g., one or more signals used in failure analysis of a DUT) over which to implement a fault search algorithm. In some cases, the test window can be defined in relation to a duration of the test pattern or a portion of the test pattern. Where an entire test pattern is used for the test window the search algorithm interrogates the entire test pattern. In the case of a binary search over the entire test pattern, the test window is defined as one half of the total duration of the test pattern. For a ternary search, the test window is defined as one third of the total duration of the test pattern. For other search algorithms, the test window can be defined in accordance with a search strategy that reduces the time, data volume, and/or number of operations taken to identify a fault in the test data.

At operation 910, example process 900 includes generating test data. Test data can include detector data (e.g., secondary electron detector data) and/or DUT output data, such that fault information generated during DUT testing can be coordinated with detector data generated by the charged particle beam system as part of associating spatial information with temporal information and signal performance information. As part of a search algorithm of example process 900, operation 910, Detector data can be generated during the test window by irradiating a portion of the DUT with a beam of charged particles, for example, as part of a device perturbation technique. For portions of the test loop outside the test window, the beam of charged particles can be blocked or otherwise interrupted (e.g., by redirecting the beam into a beam-dump). In this way, repeated operations of the example process 900 for different test windows can be used to search the overall test pattern.

As with the techniques described previously in the context of FIGS. 1-8D, the operation of a charged particle beam system can be coordinated with that of a DUT test system as an approach to addressing latency and/or bandwidth limitations of one or more data generation subsystems (e.g., detectors, communications, etc.). For example, stroboscopic techniques including phase matching can be applied to align the operation of the charged particle beam system with the DUT test system to reliably interrogate a specific portion of the test loop across multiple iterations of the test loop.

At decision 915, example process 900 includes determining whether a fault has occurred during the test window. The fault can be indicated in test data, including detector data (e.g., by voltage/contrast information in secondary electron data) and/or test output data (e.g., using the output signals of the DUT). The output of decision 915 can be used to iterate one or more operations of example process 900 as part of a search tree. Advantageously, using a search tree can improve the performance of example process 900 to more rapidly and economically (in reference to data volume and compute resource demand) identify and/or localize faults in the DUT.

At operation 920, example process 900 includes defining a new test window. For each iteration of operation 920, a rank of the test window can be incremented, in line with a progression from one tier of a search to a subsequent tier. Agnostic to the type of search algorithm being implemented, each tier can correspond to a shorter duration of the test window, such that the new test window can be shorter than the prior test window, defined in operation 905 and/or a prior iteration of operation 920. In

Additionally or alternatively, the starting point of the test window in the test pattern can differ from that of the prior test window. In the example of a binary search of the entire test pattern, a rank of one (R₁) corresponds to a duration of the test window being approximately half the duration of the test pattern. The R₁ test window can substantially cover the initial half of the test pattern. A subsequent iteration at a rank of two (R₂) corresponds to approximately one half the duration of the R₁ test window. The R₂ test window can be substantially contiguous with the R₁ test window, such that the search algorithm interrogates some of the test pattern multiple times in an attempt to reduce or avoid error introduced by signal drift. For a new test window output by operation 920, additional test data can be generated by repeating, at least in part, operation 910. To that end, the operation of the charged particle system can be modified (e.g., by altering the operation of beam control circuitry) to irradiate portion(s) of the DUT concurrent with the new test window.

In another example, a fault being detected, example process 900 can include comparing the rank of the test window to a terminal rank criterion for the search tree (e.g., described as a power of two for a binary search), at decision 925. Where the current rank is less than the terminal rank, example process can include iterating operations 920, 910, 915, and 925, to reduce the duration of the test window over which more precise techniques of operations 925 and 930 are employed. In cases where a fault is detected and the rank is less than the terminal rank criterion, operation 920 can include defining a new test window within the current test window. In contrast, where a fault is not detected, operation 920 can include defining a new test window outside and/or substantially contiguous with the current test window.

At operation 930, example process 900 includes narrowing a width of pulses of charged particles directed by the charged particle beam system. The pulse width, in this context, can be correlated to temporal resolution of detector data through parameters of the beam including beam current. The width of a pulse corresponds to a duration over which charged particles are interacting with the DUT, from which detector data can be generated. In this way, narrowing the pulse width improves the temporal resolution of detector data, at the expense of signal strength and integration time.

At operation 935, example process 900 includes searching the test window. Searching the test window can include one or more techniques for sweeping through the test window (e.g., using a phase-matching technique) based at least in part on incrementing a phase offset to probe individual time steps in the test pattern. Each time step can correspond to the temporal resolution of the charged particle beam system, with time steps being substantially contiguous (e.g., with some minimal overlap to reduce/eliminate drift error). Advantageously, using the search algorithm of example process 900 can improve the performance of fault detection techniques by limiting data volume, increasing search speed, and limiting the high resolution search to a test window of shorter duration (e.g., in reference to the rank values described above).

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on charged particle beam systems, and scanning electron microscope systems in particular, these are meant as non-limiting, illustrative embodiments. Embodiments of the present disclosure are not limited to such embodiments, but rather are intended to address analytical instruments systems for which a wide array of samples can be analyzed to determine electronic response properties, fabrication quality, and/or timing performance, among other aspects.

Some embodiments of the present disclosure include a system including one or more data processors and/or logic circuits. In some embodiments, the system includes a non-transitory computer readable storage medium containing instructions which, when executed on the one or more data processors and/or logic circuits, cause the one or more data processors and/or logic circuits to perform part or all of one or more methods and/or part or all of one or more processes and workflows disclosed herein. Some embodiments of the present disclosure include a computer-program product tangibly embodied in non-transitory machine-readable storage media, including instructions configured to cause one or more data processors and/or logic circuits to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property within which the deviation has little to no influence of the corresponding function, property, or attribute of the structure being described. In an illustrated example, where a dimensional parameter is described as “substantially equal” to another dimensional parameter, the term “substantially” is intended to reflect that the two parameters being compared can be unequal within a tolerable limit, such as a fabrication tolerance or a confidence interval inherent to the operation of the system. Similarly, where a geometric parameter, such as an alignment or angular orientation, is described as “about” normal, “substantially” normal, or “substantially” parallel, the terms “about” or “substantially” are intended to reflect that the alignment or angular orientation can be different from the exact stated condition (e.g., not exactly normal) within a tolerable limit. For numerical values, such as diameters, lengths, widths, or the like, the term “about” can be understood to describe a deviation from the stated value of up to +10%. For example, a dimension of “about 10 mm” can describe a dimension from 9 mm to 11 mm.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims. Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

What is claimed is:

1. A method for addressing beam drift artifacts in charged particle microscope images, the method comprising:
determining an acquisition window making up at least part of an integrated circuit test loop, wherein the acquisition window includes a time of interest (TOI) of the test loop;
generating detector data for a charged particle microscope system, the detector data describing a sample and corresponding to at least a portion of the acquisition window; and
generating a deflection vector for the TOI, wherein the deflection vector describes a shift in a charged particle beam induced by an electromagnetic field in the vicinity of the charged particle beam.

2. The method of claim 1, wherein generating the deflection vector comprises:
generating a sequence of images of the sample; and
generating the deflection vector using the sequence of images.

3. The method of claim 2, wherein at least a subset of the images describe a feature of the sample, and wherein generating the deflection vector further comprises:
tracking the feature of the sample in the sequence of images; and
generating shift data describing a motion of the feature in the sequence of images.

4. The method of claim 2, further comprising identifying a position on the surface of a sample using the deflection vector.

5. The method of claim 4, wherein identifying the position comprises modifying the detector data using the deflection vector.

6. The method of claim 4, further comprising, on a pixel-wise basis, generating frequency information for the position on the surface using the detector data.

7. The method of claim 6, wherein the frequency information describes an operating frequency of a device at the position.

8. The method of claim 4, wherein the detector data comprise data for multiple points in time at the position, and wherein the method further comprises generating waveform data using the detector data.

9. The method of claim 8, wherein the waveform data describe an operating voltage of a device for the multiple time points.

10. The method of claim 1, wherein the electromagnetic field is generated by a transient electrical signal applied to at least a portion of the sample.

11. The method of claim 10, wherein the transient electrical signal comprises a segment of periodic voltage.

12. A charged particle beam system, comprising:
a source of charged particles;
computing circuitry, operatively coupled with the source of charged particles; and
one or more media storing machine-readable instructions that, when executed by computing circuitry, cause the system to perform operations comprising:
determining an acquisition window making up at least part of an integrated circuit test loop, wherein the acquisition window includes a time of interest (TOI) of the test loop;
generating detector data for a charged particle microscope system, the detector data describing a sample and corresponding to at least a portion of the acquisition window; and
generating a deflection vector for the TOI, wherein the deflection vector describes a shift in a charged particle beam induced by an electromagnetic field in the vicinity of the charged particle beam.

13. The system of claim 12, wherein generating the deflection vector comprises:
generating a sequence of images of the sample; and
generating the deflection vector using the sequence of images.

14. The system of claim 13, wherein at least a subset of the images describe a feature of the sample, and wherein generating the deflection vector further comprises:
tracking the feature of the sample in the sequence of images; and
generating shift data describing a motion of the feature in the sequence of images.

15. The system of claim 12, wherein the operations further comprise identifying a position on the surface of a sample using the deflection vector.

16. The system of claim 15, wherein identifying the position comprises modifying the detector data using the deflection vector.

17. The system of claim 15, wherein the operations further comprise, on a pixel-wise basis, generating frequency information for the position on the surface using the detector data.

18. The system of claim 17, wherein the frequency information describes an operating frequency of a device at the position.

19. The system of claim 15, wherein the detector data comprise data for multiple points in time at the position, and wherein the operations further comprise generating waveform data using the detector data, the waveform data describing an operating voltage of a device for the multiple time points.

20. The system of claim 12, wherein the electromagnetic field is generated by a transient electrical signal applied to at least a portion of the sample, the transient electrical signal comprising a segment of periodic voltage.
